(19) United States
(12) Patent Application Publication
(10) Pub. No.: US 2007/0216425 A1
(43) Pub. Date: Sep. 20, 2007

(54) Capacitor apparatus

(75) Inventors: Michio Okamura, Kanagawa (JP); Takao Muto, Kanagawa (JP); Atsushi Shimizu, Kanagawa (JP)

Correspondence Address: RADER FISHMAN & GRAUER PLLC, LION BUILDING, 1233 20TH STREET N.W., SUITE 501, WASHINGTON, DC, 20036, US

(73) Assignee: Power Systems Co., Ltd., Kanagawa (JP)

(21) Appl. No.: 11/708,026

(22) Filed: Feb. 20, 2007

(30) Foreign Application Priority Data
Mar. 16, 2006 (JP) 2006-072286

(51) Int. Cl. G01R 27/26

(52) U.S. Cl. 324/678

(57) ABSTRACT

A capacitor apparatus according to the present invention is configured to charge electric charge in capacitors C1 and C2 and discharge electric charge from the capacitors C1 and C2 at normal operation time. The capacitor apparatus includes an internal resistance detection means 2 for detecting the internal resistance value of the capacitors C1 and C2 and an inter-capacitor charging/discharging control means 1 for controlling charging/discharging operation between the capacitors C1 and C2. When the internal resistance detection means 2 detects a resistance value more than a predetermined value, the inter-capacitor charging/discharging control means 1 performs charging/discharging control between the capacitors C1 and C2 to cause the capacitors C1 and C2 to self-heat.

### CROSS REFERENCES TO RELATED APPLICATIONS

This application is based upon and claims the benefit of priority from prior Japanese Patent Application No. 2006-72286, filed Mar. 16, 2006, the entire contents of which are incorporated herein by reference.

### BACKGROUND OF THE INVENTION

1. Field of the Invention

The present invention relates to a capacitor apparatus that allows a capacitor whose internal resistance has increased due to lowered temperature to self heat by current application.

2. Description of the Related Art

A high voltage and large capacity capacitor apparatus constituted by connecting a plurality of electric double layer capacitors in serial-parallel is expected to have various uses such as memory backup, power assist for electric vehicles, electric power storage, and the like and has therefore gotten a lot of attention recently. The operating principle of the electric double layer capacitor differs from a secondary battery which utilizes chemical reaction. The electric double layer capacitor simply utilizes an electric double layer, which is generated when ion in electrolyte is moved to an electrode plane along with electric charge and polarizes at the interface between the electrode and electrolyte, to generate storage capacity. Therefore, the viscosity of the electrolyte is increased as the temperature is lowered in the electric double layer capacitor to decrease the mobility of the ion, with the result that the internal resistance of the electric double layer capacitor is increased to reduce available storage capacity.

Patent Document 1 (Jpn. Pat. Appln. Laid-Open Publication No. 2002-142373) discloses a technique for improving the use efficiency of such an electric double layer capacitor at lower temperature. The capacitor apparatus of the disclosure is developed for compensating for low-temperature characteristics of a capacitor, in which the electrostatic capacitance is decreased at low temperature to increase the internal resistance of the capacitor. More specifically, the capacitor apparatus includes a temperature detection means for detecting the low temperature range in which temperature characteristics are decreased and a charging/discharging control means for compensating the temperature characteristics by increasing and decreasing the operating voltage of a capacitor in accordance with the rise and fall of the temperature detected by the temperature detection means, wherein, at lowered temperature, the operating voltage of the capacitor apparatus is increased.

Patent Document 2 (Jpn. Pat. Appln. Laid-Open Publication No. 2003-274565), which does not relate to a capacitor apparatus utilizing the electric double layer capacitor, discloses a technique for improving the operation of a secondary battery at lowered temperature. The capacitor apparatus of the disclosure includes a capacitor section having a secondary battery and capacitor connected in parallel to each other, a power generation means for charging the capacitor section, a discharge means for discharging a power from the capacitor section, and a charging/discharging controller that controls the charge and discharge operation in the capacitor section which are caused by the power generation means and discharge means, wherein in the case where the secondary battery is heated by internal heat generation caused by a repetition of charge and discharge of the secondary battery, a current value flowing in the second battery is increased to increase the temperature rising speed thereof.

### SUMMARY OF THE INVENTION

Since there is a need to detect the operating point of the capacitor apparatus “at lowered temperature”, the above techniques of both Patent Document 1 relating an electric double layer capacitor and Patent Document 2 relating to a secondary battery are provided with the temperature detection means such as a temperature sensor. That is, the technique of Patent Document 1 requires a temperature sensor for detecting the operating environment temperature of the electric double layer capacitor and, when the temperature detected by the temperature sensor is low, the operating voltage is increased. In the technique of Patent Document 2, a determination of whether the temperature-rising control is started is made based on the characteristics of a battery to be used. More specifically, whether the dischargeable output of the secondary battery is more than a level required for making a load is determined based on the temperature, current value, and terminal voltage of the secondary battery and, when it is determined “No”, the temperature-rising control is started. Thus, a process to start the temperature-rising control is very complicated. As described above, the temperature detection means is indispensable in the conventional techniques. This increases the number of parts such as a temperature sensor, resulting in an increase in cost of a system including a capacitor apparatus.

The present invention has been made to solve the above problem, and an object thereof is to provide a capacitor apparatus that uses a phenomenon that the internal resistance is increased at lowered temperature in fine pores inside a polarizable electrode (since the viscosity of the electrolyte in the fine pores is increased as the temperature is lowered to decrease the mobility of the ion) constituting the electric double layer capacitor to eliminate the need to provide the temperature detection means such as a temperature sensor.

To achieve the above object, the invention according to claim 1 is a capacitor apparatus which has a charge storage section including a first capacitor and is configured to charge electric charge in the first capacitor and discharge electric charge from the first capacitor, comprising: an internal resistance detection means for detecting the internal resistance value of the first capacitor; and an inter-capacitor charging/discharging control means having at least a second capacitor other than the first capacitor, wherein when the internal resistance detection means detects a resistance value more than a predetermined value, the inter-capacitor charging/discharging control means performs charging/discharging control between the first and second capacitors.

The invention according to claim 2 is a capacitor apparatus which has a charge storage section including a plurality of capacitors and is configured to charge electric charge in the capacitors and discharge electric charge from the capacitors, comprising: an internal resistance detection means for detecting the internal resistance value of the capacitors; and an inter-capacitor charging/discharging control means for performing charging/discharging control between the capacitors, wherein when the internal resistance detection means detects a resistance value more than a predetermined value, the inter-capacitor charging/discharging control means performs charging/discharging control between the capacitors.

The invention according to claim 3 is the capacitor apparatus as claimed in claim 1 or claim 2, wherein the internal resistance detection means detects the internal resistance value of the capacitor using an IR drop.

The invention according to claim 4 is the capacitor apparatus as claimed in any of claims 1 to 3, wherein the inter-capacitor charging/discharging control means includes a buck-boost converter.

The invention according to claim 5 is the capacitor apparatus as claimed in any of claims 1 to 3, wherein the inter-capacitor charging/discharging control means includes a switching regulator.

The capacitor apparatus according to the present invention uses the internal resistance detection means to detect an increase in the internal resistance value of the capacitor and uses the inter-capacitor charging/discharging means to repeat charging/discharging control between capacitors based on the detection result to cause current to flow to heat the internal resistance to thereby increase the capacitor temperature. As a result, the internal resistance of the capacitor is reduced in a self-healing manner. Therefore, it is possible to detect the internal resistance of the capacitor without need to provide a temperature sensor which is indispensable in a conventional capacitor apparatus, thereby reducing cost of a system of the capacitor apparatus.

### BRIEF DESCRIPTION OF THE DRAWINGS

FIG. 1 is a view showing the operating principle of a capacitor apparatus according to an embodiment of the present invention;

FIG. 2 is a view showing an example of a capacitor apparatus according to the embodiment of the present invention;

FIG. 3 is a view showing an equivalent circuit of the circuit example of the capacitor apparatus according to the embodiment of the present invention;

FIG. 4 is a view showing the operating principle of a capacitor apparatus according to another embodiment of the present invention;

FIG. 5 is a view explaining the operating principle of the capacitor apparatus according to the another embodiment of the present invention using a capacitor apparatus including three capacitors;

FIG. 6 is a view showing an example of a capacitor apparatus according to the another embodiment of the present invention;

FIG. 7 is a view showing an equivalent circuit of the circuit example of the capacitor apparatus according to the another embodiment of the present invention;

FIG. 8 is a view showing the entire system of the capacitor apparatus according to the embodiment of the present invention;

FIG. 9 is the flowchart of a process for controlling the system of the capacitor apparatus according to the embodiment of the present invention; and

FIG. 10 is a view showing another example of the system of the capacitor apparatus according to the embodiment of the present invention.

### DETAILED DESCRIPTION OF THE PREFERRED EMBODIMENTS

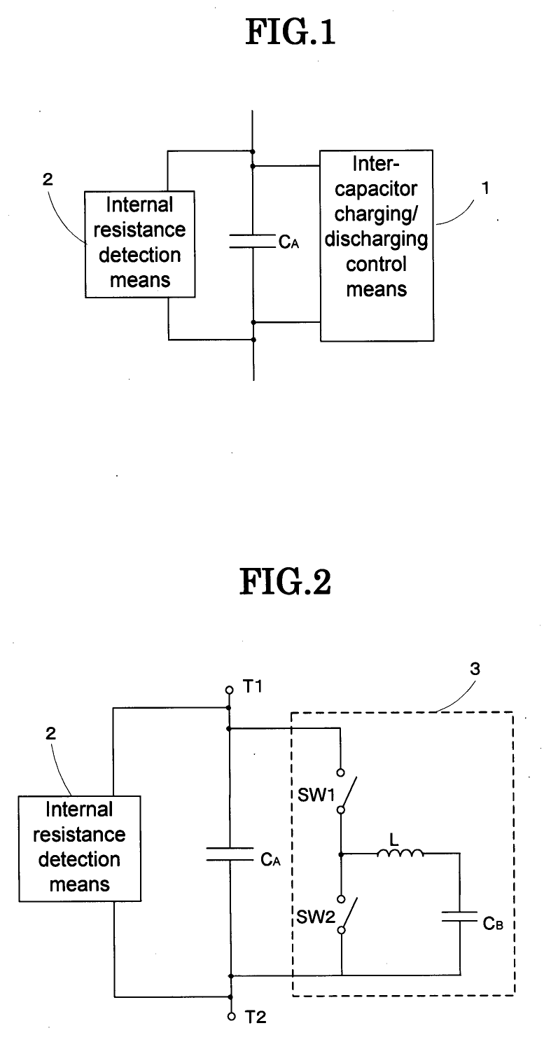

An embodiment of the present invention will be described below with reference to the accompanying drawings. FIG. 1 is a view showing the operating principle of a capacitor apparatus according to an embodiment of the present invention, and FIG. 2 is a view showing an example of a capacitor apparatus according to the embodiment of the present invention. The capacitor apparatus of FIG. 1 charges/discharges electric charge in/from a capacitor C_{A} at normal operation time. FIG. 1 shows a part of the capacitor apparatus in an extracted manner in order to explain the operating principle of the present invention. In the present embodiment, an electric double layer capacitor is used as the capacitor C_{A}. In FIG. 1, numeral 1 is an inter-capacitor charging/discharging control means and 2 is an internal resistance detection means. The internal resistance detection means 2 is connected in parallel to the capacitor C_{A} and detects the internal resistance of the capacitor C_{A}. The inter-capacitor charging/discharging control means 1 is connected in parallel to the capacitor C_{A} and charges electric charge accumulated in the capacitor C_{A} in a storage means provided in the inter-capacitor charging/discharging control means 1 or conversely charges electric charge accumulated in the storage means in the capacitor C_{A}. The inter-capacitor charging/discharging control means 1 can be constituted by a capacitor, an inductor, a switching element, a diode, and the like. The outline of the operation of the capacitor apparatus of the present invention having the above configuration will be described. Firstly, the internal resistance detection means 2 detects the internal resistance value of the capacitor C_{A}. When it is determined that the detected value exceeds a predetermined value, the inter-capacitor charging/discharging control means 1 starts charging/discharging control to charge electric charge accumulated in the capacitor C_{A} in a storage means provided in the inter-capacitor charging/discharging control means 1 or conversely charge electric charge accumulated in the storage means in the capacitor C_{A}. Such operation is performed because it can be determined that when the internal resistance value of the capacitor C_{A} exceeds a predetermined value, the capacitor C_{A} is in a low temperature environment. When the inter-capacitor charging/discharging control means 1 performs the above charging/discharging control, current flows in the internal resistance of the capacitor C_{A} to heat the internal resistance of the capacitor C_{A}. The capacitor C_{A} is thus self-heated to thereby reduce the internal resistance of the capacitor C_{A} in a self-healing manner. As described above, the capacitor apparatus according to the present invention activates the inter-capacitor charging/discharging control means based on the internal resistance value of the capacitor and heats the internal resistance of the capacitor with charging/discharging current between capacitors to thereby increase the temperature of the capacitor to reduce the internal resistance without a use of a temperature detection means such as a temperature sensor. Therefore, it is possible to constitute a capacitor apparatus at low cost without need to provide a component such as a temperature sensor which is indispensable in a conventional capacitor apparatus.

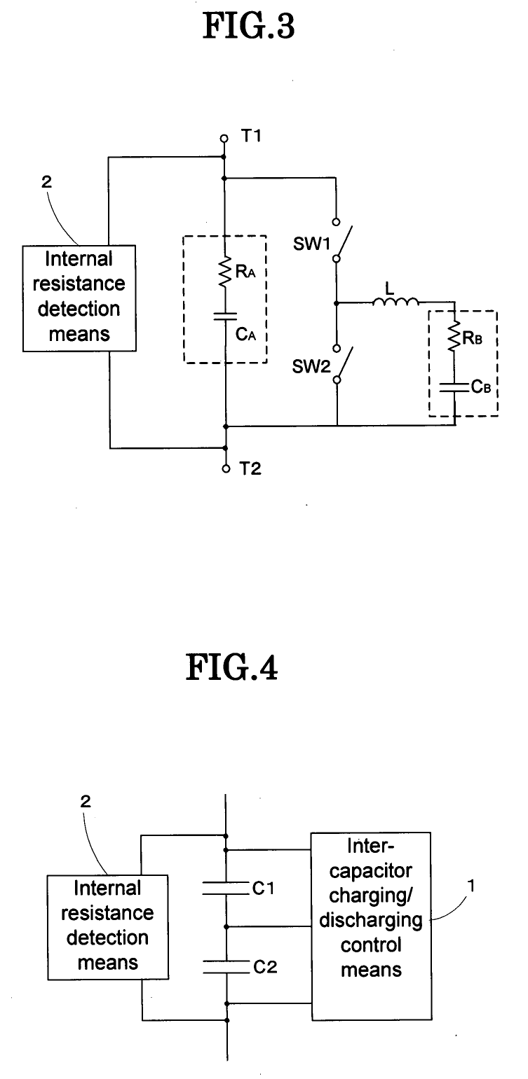

FIG. 2 shows an example of the circuit configuration of the inter-capacitor charging/discharging control means 1 of FIG. 1. In FIG. 2, C_{A} and C_{B} are capacitors, L is an inductor, SW1 and SW2 are switching elements, and T1 and T2 are terminals. The part surrounded by the dotted line 3 in FIG. 2 corresponds to the inter-capacitor charging/discharging control means 1 shown in FIG. 1. FIG. 3 is a view showing an equivalent circuit of the circuit example of the capacitor apparatus shown in FIG. 2. In FIG. 3, the parts surrounded by the dotted line show the capacities C_{A} and C_{B} of the capacitors C_{A} and C_{B}, as well as the internal resistances R_{A} and R_{B} thereof, respectively. The internal resistance of the inductor L is omitted here. The following description will be made based on FIG. 3.

In FIG. 3, each of the capacitors C_{A} and C_{B} uses, for example, an electric double layer capacitor. The inter-capacitor charging/discharging control means 1, which includes the capacitor C_{B}, alternately repeats charging electric charge in the capacitor C_{B} from capacitor C_{A} and, conversely, charging electric charge in the capacitor C_{A} from capacitor C_{B} to thereby cause the abovementioned current for heating the internal resistance of the capacitor to flow. The terminals T1 and T2 of both ends of the capacitor C_{A} are connected to a not shown charging/discharging control circuit and used to charge electric charge in the capacitor C_{A} and discharge electric charge from the capacitor C_{A} at normal operation time. A series circuit of the switching elements SW1 and SW2 are connected in parallel to the capacitor C_{A}. The inductor L and capacitor C_{B} are connected between the midpoint of the series connection of the switching elements SW1 and SW2 and switching element SW2. When one switching element SW1 (or SW2) performs switching control, the other switching element SW2 (or SW1) operates as a synchronous rectifier and thereby the switching elements SW1 and SW2 serve as a buck-boost converter for transferring electric charge and charging current of one capacitor to the other capacitor.

Next, the operation of the circuit shown in FIG. 3 will be described. When the internal resistance detection means 2 detects the internal resistance R_{A} of the capacitor C_{A} and it is determined that the internal resistance value R_{A} exceeds a predetermined value in the configuration as described above, the switching elements SW1 and SW2 are controlled to transfer electric charge (to cause current to flow) from capacitor C_{A} to capacitor C_{B} or from capacitor C_{B} to capacitor C_{A}. The electric charge of the capacitor C_{A} is used for the charging of the capacitor C_{B} by the buck-boost converter constituted by the switching element SW1, inductor L, and switching element SW2 operating as the synchronous rectifier. After the charging from the capacitor C_{A} to capacitor C_{B} for a predetermined time in this manner, the charging from the capacitor C_{B} to capacitor C_{A} is performed. That is, the electric charge of the capacitor C_{B} is charged in the capacitor C_{A} by the buck-boost converter constituted by the switching element SW2, inductor L, and switching element SW1 operating as the synchronous rectifier. The repetition of such operation controls the buck-boost converter to cause current to flow from the capacitor C_{A} to capacitor C_{B} or from capacitor C_{B} to capacitor C_{A} to thereby heat the internal resistance R_{A}. As a result, the temperature of the capacitor C_{A} is increased, thereby reducing the internal resistance R_{A}.

The operation of the buck-boost converter will be described with the charging from the capacitor C_{A} to capacitor C_{B} taken as an example. Firstly, the switching element SW1 is closed while the switching element SW2 is opened to cause current to flow from the capacitor C_{A} through resistance R_{A}, switching element SW1, inductor L, and resistance R_{B}, to the capacitor C_{B}. Subsequently, the switching element SW1 is opened while the switching element SW2 is closed. Then, the current flowing in the inductor L tends to flow along, so that current flows from the inductor L, through resistance R_{B}, capacitor C_{B}, to the switching element SW2. Subsequently, the switching element SW1 is closed while the switching element SW2 is opened once again to cause current to flow from the capacitor C_{A} through resistance R_{A}, switching element SW1, inductor L, and resistance R_{B}, to the capacitor C_{B} to thereby charge electric charge in the capacitor C_{B}.

The capacitor apparatus according to the present invention detects an increase of the internal resistance value in the manner as described above to repeat charging/discharging control between capacitors to cause current to flow to heat the internal resistance to thereby increase the temperature of the capacitor. The transfer of electric charge between the capacitors C_{A} and C_{B} is achieved by current switching control of the switching element, so that less energy consumption is required, resulting in high efficiency.

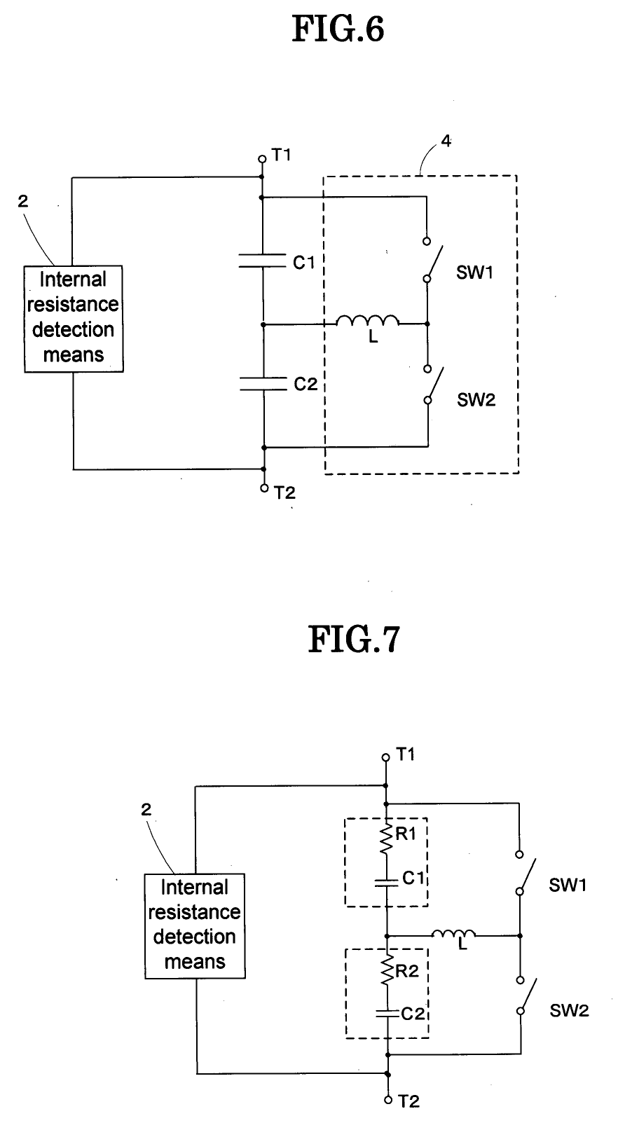

FIG. 4 is a view showing the operating principle of a capacitor apparatus according to another embodiment of the present invention, and FIG. 6 is a view showing an example of a capacitor apparatus according to another embodiment of the present invention. The capacitor apparatus of FIG. 4 charges/discharges electric charge in/from series-connected capacitors C1 and C2 at normal operation time. FIG. 4 shows a part of the capacitor apparatus in an extracted manner in order to explain the operating principle of another embodiment of the present invention. In the present embodiment, an electric double layer capacitor is used as the capacitors C1 and C2. In FIG. 1, numeral 1 is the inter-capacitor charging/discharging control means and 2 is the internal resistance detection means. The internal resistance detection means 2 is connected in parallel to the series-connected capacitors C1 and C2 and detects the internal resistance of the capacitors C1 and C2. The inter-capacitor charging/discharging control means 1 is connected at three points (both end points of the series-connected capacitors C1 and C2 and point between the capacitors C1 and C2) to the capacitors C1 and C2 and transfers electric charge accumulated in the capacitor C1 to the capacitor C2 or conversely transfers electric charge accumulated in the capacitor C2 to the capacitor C1. The inter-capacitor charging/discharging control means 1 can be constituted by a capacitor, an inductor, a switching element, a diode, and the like.

The outline of the operation of the capacitor apparatus of the present invention having the above configuration will be described. Firstly, the internal resistance detection means 2 detects the sum of the internal resistance values of the capacitors C1 and C2. When it is determined that the detected values exceed a predetermined value, the inter-capacitor charging/discharging control means 1 starts charging/discharging control to transfer electric charge accumulated in the capacitor C1 to the capacitor C2 or conversely transfer electric charge accumulated in the capacitor C2 to the capacitor C1. Such operation is performed because it can be determined that when the internal resistance values of the capacitors C1 and C2 exceed a predetermined value, the capacitors C1 and C2 are in a low temperature environment. When the inter-capacitor charging/discharging control means 1 performs the above charging/discharging control, current flows in the internal resistance of the capacitors C1 and C2 to heat the internal resistance of the capacitors C1 and C2. The capacitors C1 and C2 are thus self-heated to thereby reduce the internal resistance of the capacitors C1 and C2 in a self-healing manner. As described above, the capacitor apparatus according to the present invention activates the inter-capacitor charging/discharging control means based on the internal resistance values of the capacitors and heats the internal resistance of the capacitors with charging/discharging current between capacitors to thereby increase the temperatures of the capacitors to reduce the internal resistance without a use of a temperature detection means such as a temperature sensor. Therefore, it is possible to constitute a capacitor apparatus at low cost without need to provide a component such as a temperature sensor which is indispensable in a conventional capacitor apparatus.

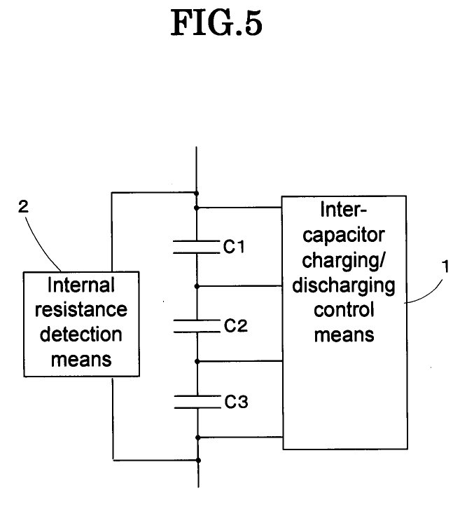

Although the capacitor apparatus including the two capacitors C1 and C2 are shown in FIG. 4, the present invention can be applied to a capacitor apparatus including two or more capacitors. FIG. 5 is a view explaining the operating principle of the capacitor apparatus according to the another embodiment of the present invention using a capacitor apparatus including three capacitors. The inter-capacitor charging/discharging control means 1 and internal resistance detection means 2 are connected to the series-connected capacitors C1, C2, and C3 at the portions shown in FIG. 5. For example, the inter-capacitor charging/discharging control means 1 performs charging/discharging control to transfer electric charge accumulated in the capacitor C1 to the capacitor C2 and/or capacitor C3, transfer the electric charge accumulated in the capacitor C2 to the capacitor C1 and/or capacitor C3 or transfer the electric charge accumulated in the capacitor C3 to the capacitor C1 and/or capacitor C2. The point is, in the present invention, also in the case where the capacitor apparatus including three or more capacitors, electric charge is transferred between the capacitors constituting the capacitor apparatus to cause current to flow to heat the internal resistance of the capacitors.

FIG. 6 shows an example of the circuit configuration of the inter-capacitor charging/discharging control means 1 shown in FIG. 4. In FIG. 6, C1 and C2 are capacitors, L is an inductor, SW1 and SW2 are switching elements, and T1 and T2 are terminals. The part surrounded by the dotted line 4 in FIG. 6 corresponds to the inter-capacitor charging/discharging control means 1 shown in FIG. 4. FIG. 7 is a view showing an equivalent circuit of the circuit example of the capacitor apparatus shown in FIG. 6. In FIG. 7, the parts surrounded by the dotted line show the capacities C1 and C2 of the capacitor C1 and C2, as well as the internal resistances R1 and R2 thereof, respectively. The internal resistance of the inductor L is omitted here. The following description will be made based on FIG. 7.

In FIG. 7, each of the series-connected capacitors C1 and C2 uses an electric double layer capacitor. The terminals T1 and T2 of both ends of the series-connected capacitors C1 and C2 are connected to a not shown charging/discharging control circuit and used to charge electric charge in the capacitors C1 and C2 and discharge electric charge from the capacitors C1 and C2 at normal operation time. A series circuit of the switching elements SW1 and SW2 are connected in parallel to the series circuit of the capacitors C1 and C2. The inductor L is connected between the midpoint of the series connection of the capacitors C1 and C2 and the midpoint of the series connection of switching elements SW1 and SW2. When one switching element SW1 (or SW2) performs switching control, the other switching element SW2 (or SW1) operates as a synchronous rectifier and thereby the switching elements SW1 and SW2 serve as a buck-boost converter for transferring electric charge and charging current of one capacitor to the other capacitor.

Next, the operation of the circuit shown in FIG. 7 will be described: When the internal resistance detection means 2 detects the sum of the internal resistance R1 and R2 of the capacitors C1 and C2 and it is determined that the detected internal resistance value exceeds a predetermined value in the configuration as described above, the switching elements SW1 and SW2 are controlled to transfer electric charge (to cause current to flow) from capacitor C1 to capacitor C2 or from capacitor C2 to capacitor C1. The operation of the buck-boost converter will be described with the charging from the capacitor C1 to capacitor C2 taken as an example. Firstly, the switching element SW1 is closed while the switching element SW2 is opened to cause current to flow from the capacitor C1 through resistance R1, switching element SW1, to the inductor L. Subsequently, the switching element SW1 is opened while the switching element SW2 is closed. Then, the current flowing in the inductor L tends to flow along, so that current flows from the inductor L, through resistance R2, capacitor C2, to the switching element SW2 to thereby charge electric charge in the capacitor C2. The operation of the buck-boost converter is controlled in this manner to cause current to flow from the capacitor C1 to capacitor C2 or from capacitor C2 to capacitor C1 to thereby heat the internal resistance R1 and R2. As a result, the temperatures of the capacitors C1 and C2 are increased, thereby reducing the internal resistances R1 and R2.

The capacitor apparatus according to the present invention detects an increase of the internal resistance value in the manner as described above to repeat charging/discharging control between capacitors to cause current to flow to heat the internal resistance to thereby increase the temperature of the capacitor. The transfer of electric charge between the capacitors C1 and C2 is achieved by current switching control of the switching element, so that less energy consumption is required, resulting in high efficiency. Further, since the charging/discharging control is performed between the capacitors C1 and C2, the power loss is limited to the value corresponding to that generated in the internal resistance in a theoretical sense, so that the power loss can be reduced to a minimum.

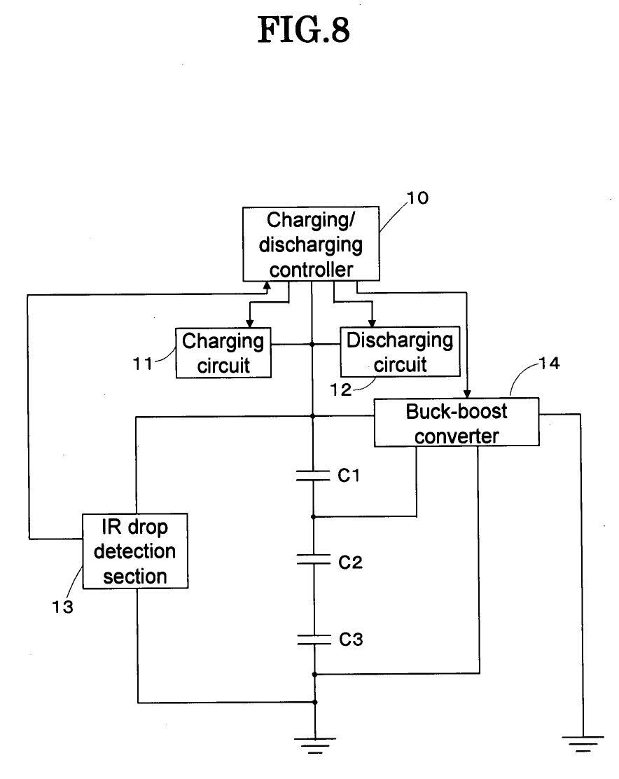

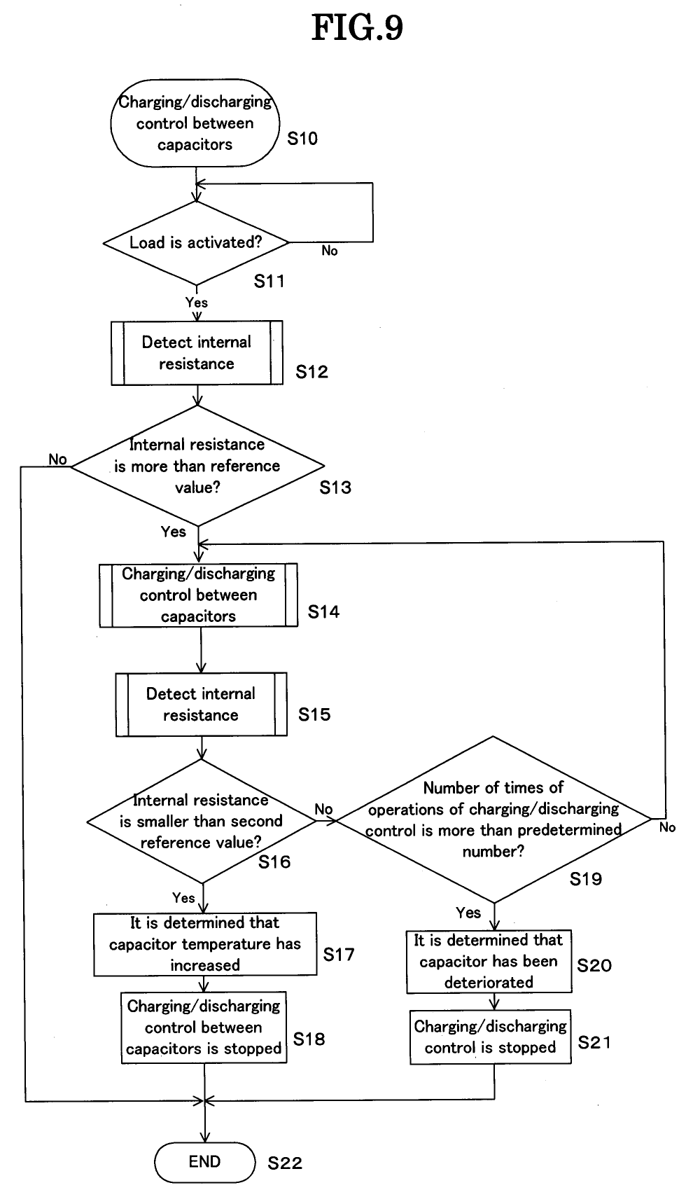

Next, a case where the present invention is applied to a system of the capacitor apparatus will be described with reference to FIGS. 8 and 9. FIG. 8 is a view showing the entire system of the capacitor apparatus according to the embodiment of the present invention. FIG. 9 is a flowchart of a process for controlling the system of the capacitor apparatus according to the embodiment of the present invention. In the system of the capacitor apparatus shown in FIG. 8 C1, C2, and C3 are (electric double layer) capacitors, 10 is a charging/discharging controller, 11 is a charging circuit, 12 is a discharging circuit, 13 is an IR drop detection section, and 14 is a buck-boost converter.

In the system of the capacitor apparatus according to the present invention, the charging/discharging controller 10 controls the charging circuit 11 including a power source and the like to charge electric charge in the series-connected capacitors C1, C2, and C3 as well as controls the discharging circuit 12 including a load and the like to discharge electric charge from the capacitors C1, C2, and C3 at normal operation time. Although an electric double layer capacitor is taken as an example of the capacitors C1, C2, and C3, other types of capacitors or a secondary battery may be used. In the system of the capacitor apparatus shown in FIG. 8, the IR drop detection section 13 is used as an example of the component corresponding to “internal resistance detection means” that has been described until now. The IR drop is a phenomenon a voltage value immediately after the start of the discharge of the capacitor decreases in a stepwise manner. Based on the IR drop, the internal resistance of the capacitor can be calculated. The IR drop detection section 13 uses the IR drop to detect the internal resistance of the capacitors C1, C2, and C3.

The charging/discharging controller 10 receives signals from the parallel monitors 5, 5′, and 5″ and IR drop detection section 13 and controls the buck-boost converter 14. That is, the charging/discharging controller 10 and buck-boost converter 14 constitute the component corresponding to “inter-capacitor charging/discharging control means 1” that has been described until now. The charging/discharging controller 10 controls the buck-boost converter 14 to perform charging/discharging control to thereby transfer electric charge accumulated in the capacitor 1 to the capacitors 2 and 3 or transfer electric charge accumulated in the capacitors 2 and 3 to the capacitor 1. Electric charge is thus transferred between the capacitors C1, C2, and C3 to cause current to flow, with the result that the internal resistance of the capacitors C1, C2, and C3 is heated to thereby increase the temperatures of the capacitors C1, C2, and C3.

Next, the flow of a process for controlling the system of the capacitor apparatus having the configuration described above will be described. In FIG. 9, the charging/discharging control between capacitors is started in step S10, and whether discharge control for a not shown load is to be made or not (whether a load is activated or not) is monitored in step S11. When it is determined that the discharge control is not to be made (a load is not activated), the flow loops around step S11. When it is determined in step S11 that the discharge control is to be made (a load is activated), the IR drop detection section 13 detects the internal resistance of the capacitors C1, C2, and C3 in step S12.

Then, the flow advances to step S13, where it is determined whether the sum of the internal resistance value of the capacitors C1, C2, and C3 detected by the IR drop detection section 13 exceeds a predetermined first reference value. When it is determined that the sum of the internal resistance value of the capacitors C1, C2, and C3 does not exceed the first reference value, the flow advances to step S22, and is ended. On the other hand, when it is determined in step S13 that the sum of the internal resistance value of the capacitors C1, C2, and C3 exceeds the first reference value, it means that the temperatures of the capacitors C1, C2, and C3 can be assumed to be decreased and, then, the flow advances to step S14, where the inter-capacitor charging/discharging control means constituted by the charging/discharging controller 10 and buck-boost converter 14 performs charging/discharging control between the capacitors C1, C2, and C3. The procedure of the charging/discharging control between the capacitors C1, C2, and C3 is as described above. Subsequently, in step S15, the IR drop detection section 13 detects the sum of the internal resistance value of the capacitors C1, C2, and C3 once again.

Then, in step S16, it is determined whether the sum of the detected internal resistance values of the capacitors C1, C2, and C3 is smaller than a second reference value. Although the second reference value is newly provided here, this reference value may be the first reference value, depending on the system design. When it is determined that the sum of the detected internal resistance values of the capacitors C1, C2, and C3 is smaller than the second reference value in step S16, the flow advances to step S17. Since the sum of the detected internal resistance values of the capacitors C1, C2, and C3 has become smaller than the second reference value, it can be determined in step S17 that the capacitor temperature has been increased by the charging/discharging control between capacitors performed in step S14. Therefore, the capacitor charging/discharging control between capacitors is stopped in step S18 and this flow is ended in S22.

When it is determined that the sum of the detected internal resistance values of the capacitors C1, C2, and C3 is smaller than the second reference value in step S16, the flow advances to step S19. In step S19, it is determined whether the number of times of operations of the charging/discharging control between capacitors is more than a predetermined number. If the number of times of operations of the charging/discharging control between capacitors is less than a predetermined number, it can be considered that the capacitor temperature has not increased to a level sufficient to reduce the internal resistance of the capacitor and therefore the number of times of operations of the charging/discharging control is still insufficient. Thus, the flow returns to step S14, where the charging/discharging control between capacitors is performed. When it is determined in step S19 that the number of times of operations of the charging/discharging control between capacitors is more than a predetermined number, it can be determined in step S20 that the reason why the internal resistance of the capacitor is not reduced is that there is abnormality such as deterioration in the capacitor. Therefore, the charging/discharging control is stopped in step S21, and the flow is ended in step S22. The reason why the above processing has been made is that in the case where it is determined in step S19 that the number of times of operations of the charging/discharging control between capacitors is more than a predetermined number, it can be considered that the reason why the internal resistance of the capacitor is not reduced even though the charging/discharging control has been performed by a number sufficient to expect that the capacitor temperature increases is that there is abnormality such as deterioration in the capacitor.

As described above, the system of the capacitor apparatus according to the present invention uses the IR drop detection section 13 to detect an increase of the internal resistance value and, based on the detection result, repeats the charging/discharging control between capacitors to cause current to flow to heat the internal resistance to thereby increase the capacitor temperature. The transfer of electric charge between the capacitors C1, C2, and C3 is performed under the control of the buck-boost converter 14, so that less energy consumption is required, resulting in high efficiency. Further, since the charging/discharging control is performed between the capacitors C1, C2, and C3, the power loss is limited to the value corresponding to that generated in the internal resistance in a theoretical sense, so that the power loss can be reduced to a minimum. Further, even if the internal resistance is not reduced after the repetition of the charging/discharging control between capacitors, it can be determined that there is abnormality such as deterioration in the capacitor, eliminating the need to provide additional capacitor abnormality detection section.

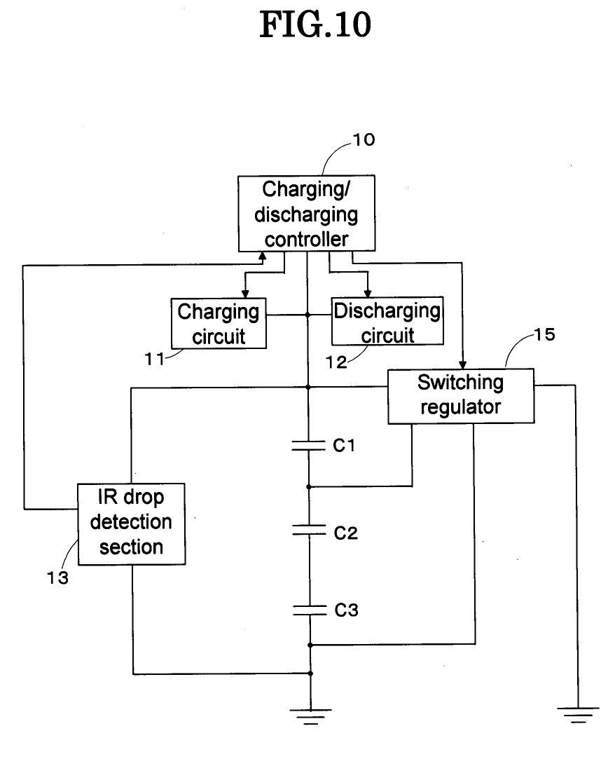

In the system of the capacitor apparatus according to the present invention, as shown in FIG. 10, a switching regulator 15 may be used in place of the buck-boost converter 14. FIG. 10 is another example of the system of the capacitor apparatus according to the embodiment of the present invention. The system shown in FIG. 10 can obtain the same effect as the system using the buck-boost converter 14.

1. A capacitor apparatus which has a charge storage section including a first capacitor and is configured to charge electric charge in the first capacitor and discharge electric charge from the first capacitor, comprising:
internal resistance detection means for detecting the internal resistance value of the first capacitor; and
inter-capacitor charging/discharging control means having at least a second capacitor other than the first capacitor, wherein
when the internal resistance detection means detects a resistance value more than a predetermined value, the inter-capacitor charging/discharging control means performs charging/discharging control between the first and second capacitors.

2. A capacitor apparatus which has a charge storage section including a plurality of capacitors and is configured to charge electric charge in the capacitors and discharge electric charge from the capacitors, comprising:
internal resistance detection means for detecting the internal resistance value of the capacitors; and
inter-capacitor charging/discharging control means for performing charging/discharging control between the capacitors, wherein
when the internal resistance detection means detects a resistance value more than a predetermined value, the inter-capacitor charging/discharging control means performs charging/discharging control between the capacitors.

3. The capacitor apparatus according to claim 1 or claim 2, wherein the internal resistance detection means detects the internal 5 resistance value of the capacitor using an IR drop.

4. The capacitor apparatus according to claim 1 or claim 2, wherein
the inter-capacitor charging/discharging control means includes a buck-boost converter.

5. The capacitor apparatus according to claim 1 or claim 2, wherein
the inter-capacitor charging/discharging control means includes a switching regulator.

6. The capacitor apparatus according to claim 3, wherein
the inter-capacitor charging/discharging control means includes a buck-boost converter.

7. The capacitor apparatus according to claim 3, wherein
the inter-capacitor charging/discharging control means includes a switching regulator.
